(19) United States
(12) Patent Application Publication
(10) Pub. No.: US 2008/0308954 A1
(43) Pub. Date: Dec. 18, 2008

(54) Semiconductor device and method of forming the same

(76) Inventor: Seok-Chang Seo, Suwon-si (KR)

Correspondence Address: LEE & MORSE, P.C., 3141 FAIRVIEW PARK DRIVE, SUITE 500, FALLS CHURCH, VA, 22042, US

(21) Appl. No.: 12/155,970

(22) Filed: Jun. 12, 2008

(30) Foreign Application Priority Data
Jun. 12, 2007 (KR) 2007-57409

(51) Int. Cl. H01L 21/768; H01L 23/522

(52) U.S. Cl. 257/786; 438/618; 257/E23.142; 257/E21.59

(57) ABSTRACT

A semiconductor device includes conductive lines on a substrate, sidewall spacers on sidewalls of the conductive lines, contacts between the conductive lines, the contacts separated from the conductive lines by the sidewall spacers and electrically connected to active regions of the substrate, contact pads on and electrically connected to corresponding contacts, protection patterns contacting side surfaces of the contact pads, the protection patterns being disposed between the contact pads in a first direction crossing the conductive lines, and storage nodes on and electrically connected to corresponding contact pads.

### BACKGROUND OF THE INVENTION

1. Field of the Invention

Embodiments relate to a semiconductor device and a method of forming the same and, more particularly, to a semiconductor device including a contact pad and a method of forming the same.

2. Description of the Related Art

A unit cell of a dynamic random access memory (DRAM) device includes a transistor and a capacitor, and DRAM devices exhibiting high speed and large capacitance are desired. Generally, device density may be increased by reducing a design rule. However, it is desirable to increase an area of a storage node in order to provide a capacitor with high capacitance. In order to achieve high capacitance while reducing a layout area, or footprint, the aspect ratio of a storage node may be increased. As a result, an area of a lower portion of the storage node may be reduced.

A DRAM device may be formed with multiple layers to integrate the unit device on a small area, and may include a contact penetrating an interlayer dielectric. However, since an area of a lower portion of the storage node may be reduced in a high aspect ratio device, it may be difficult to form a contact to a storage node. Moreover, improperly formed contacts may degrade reliability of the semiconductor device. Accordingly, there is a need for a semiconductor device having a design that enables the formation of reliable contacts, and a method of forming the same.

### SUMMARY OF THE INVENTION

Embodiments are therefore directed to a semiconductor device including a contact pad and a method of forming the same, which substantially overcome one or more of the problems due to the limitations and disadvantages of the related art.

It is therefore a feature of an embodiment to provide a semiconductor device including a contact pad and a method of forming the same, which provide an alignment margin for a connection with a storage node.

At least one of the above and other features and advantages may be realized by providing a semiconductor device, including conductive lines on a substrate, sidewall spacers on sidewalls of the conductive lines, contacts between the conductive lines, the contacts separated from the conductive lines by the sidewall spacers and electrically connected to active regions of the substrate, contact pads on and electrically connected to corresponding contacts, protection patterns contacting side surfaces of the contact pads, the protection patterns being disposed between the contact pads in a first direction crossing the conductive lines, and storage nodes on and electrically connected to corresponding contact pads.

A bottom surface of the contact pad may be wider in the first direction than an opposing top surface of the corresponding contact. A top surface of the contact pad may be wider in the first direction than an opposing bottom surface of a corresponding storage node. The storage nodes may be substantially centered on the contact pads. At least some of the storage nodes may be offset in the first direction with respect to the corresponding contact pads.

The device may further include an interlayer dielectric directly under portions of the contact pads, and bottom spacers on an upper surface of the interlayer dielectric below the portions of the contact pads, wherein the bottom spacers include silicon nitride. The device may further include a capping material on top surfaces of the conductive lines, the capping material and the bottom spacers being a same material. The contact pads may be in contact with the capping line. The sidewall spacers may be in contact with the contact pads, and the sidewall spacers and the bottom spacers may be the same material. The protection patterns may have a same height as the portions of the contact pads. The device may be a DRAM.

At least one of the above and other features and advantages may also be realized by providing a method of forming a semiconductor device, including forming conductive lines on a substrate, forming sidewall spacers on sidewalls of the conductive lines, forming contacts between the conductive lines, the contacts separated from the conductive lines by the sidewall spacers and electrically connected to active regions of the substrate, forming contact pads on and electrically connected to corresponding contacts, forming protection patterns contacting side surfaces of the contact pads, the protection patterns being disposed between the contact pads in a first direction crossing the conductive lines, and forming storage nodes on and electrically connected to corresponding contact pads.

The method may further include forming a spacer layer over a first insulating layer between the conductive lines, forming a second insulating layer on the spacer layer, planarizing the second insulating layer using the spacer layer as a stop layer, forming a first etching mask on the planarized second layer, and anisotropically etching the first insulating layer through openings in the first etching mask, wherein the first insulating layer forms the sidewall spacers on the conductive lines.

A capping pattern may be formed on each conductive line, the capping patterns each having a width substantially equal to the underlying conductive line, and the spacer layer may be formed on a top surface and sidewalls of each capping pattern.

Forming the protection patterns may include etching portions of the second insulating layer to expose the spacer layer and form a plurality of linear open regions, filling the open regions with a protection material, and planarizing the protection material using the spacer layer as a stop layer. Forming the open regions may include forming a second etching mask on the spacer layer and on the second insulating layer, the second etching mask having openings that cross the conductive lines, and etching the second insulating layer through the openings in the second etching mask using an etching operation that etches the second insulating layer faster than the spacer layer.

The method may further include isotropically etching the second insulating layer overlying the spacer layer using the first etching mask to define contact pad regions in the second insulating layer. The first etching mask may include polysilicon, the spacer layer and the protection patterns may include silicon nitride, and the second insulating layer may include silicon oxide.

Forming the protection patterns may include forming one first protection pattern and two second protection patterns between adjacent contact pads, each first protection pattern may be formed between a pair of second protection patterns, and the second protection patterns may protect the first protection patterns during an etching operation used to define contact pad regions between adjacent second protection patterns. The etching operation may be isotropic, and a first etching mask may be formed to cover the one first protection pattern and two second protection patterns between the adjacent contact pads prior to the etching operation.

At least one of the above and other features and advantages may also be realized by providing a method of forming a semiconductor device, including forming a first insulating layer exposing a top surface and an upper portion of a side surface of line patterns on a substrate, forming a spacer layer on the first insulating layer and the exposed surface of the line patterns, forming an insulating pattern on the spacer layer to fill a space between the line patterns, forming protection patterns in contact with the spacer layer along a direction of crossing the line patterns in the insulating pattern, defining a contact pad region between the protection patterns, defining a contact region exposing the substrate by etching the spacer layer and the first insulating layer through the contact pad region, filling the contact region and the contact pad region with conductive material to form a contact and a contact pad, and forming a storage node on the contact.

### BRIEF DESCRIPTION OF THE DRAWINGS

The above and other features and advantages will become more apparent to those of ordinary skill in the art by describing in detail exemplary embodiments with reference to the attached drawings, in which:

FIGS. 1A, 2A and 3A illustrate top plan views of a semiconductor device according to embodiments;

FIGS. 1B, 2B and 3B illustrate cross sectional views of the semiconductor device illustrated in FIGS. 1A, 2A and 3A, respectively, taken along the lines of I-I′ and II-II′ of FIGS. 1A, 2A and 3A;

FIGS. 4A through 16A illustrate top plan views of stages in a method of forming a semiconductor device according to embodiments; and

FIGS. 4B through 16B illustrate cross sectional views of stages in the method of forming the semiconductor device illustrated in FIGS. 4A through 16A, respectively, taken along the lines I-I′ and II-II′ of FIGS. 4A through 16A.

### DETAILED DESCRIPTION OF THE INVENTION

Korean Patent Application No. 2007-57409, filed on Jun. 12, 2007, in the Korean Intellectual Property Office, and entitled: “Semiconductor Device and Method of Forming the Same,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

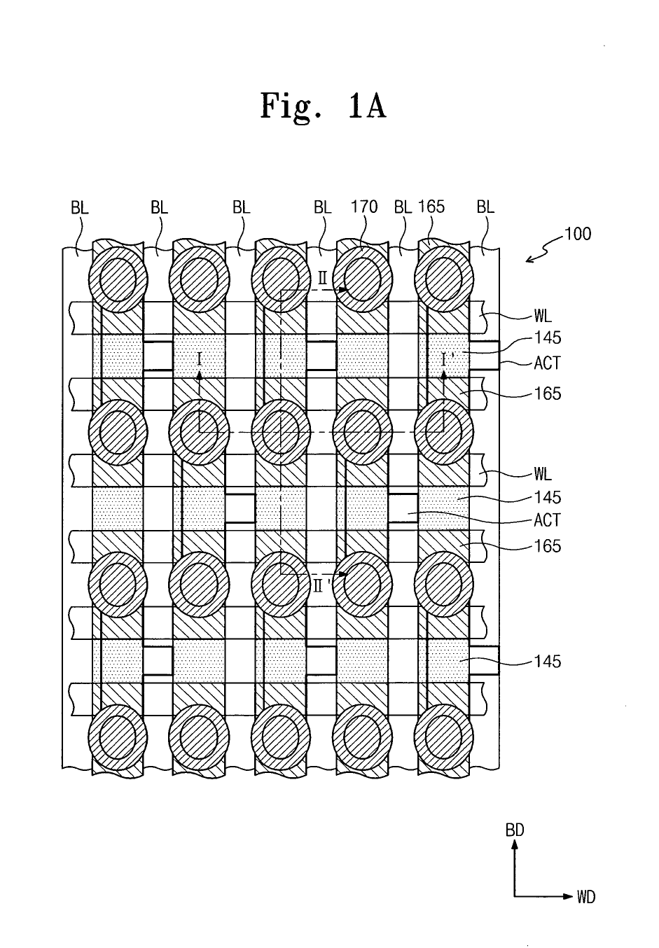

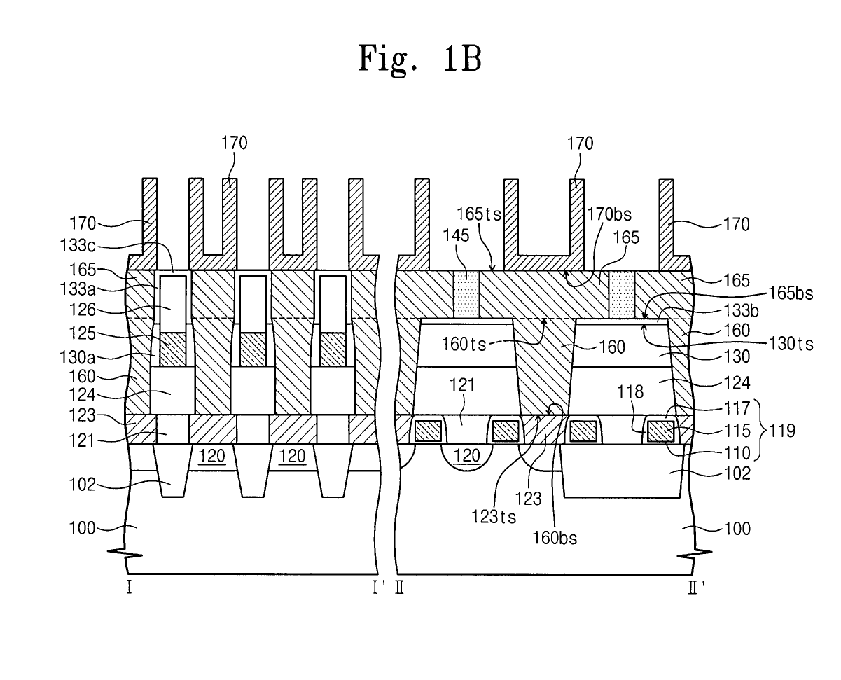

In connection with FIGS. 1A-B, 2A-B and 3A-B, semiconductor devices will now be described in accordance with first, second and third embodiments, respectively.

Referring to FIGS. 1A and 1B, word lines WL may extend parallel to a first direction WD on a substrate 100. An active region ACT may be defined on the substrate 100 by a device isolation layer 102. An impurity region 120 may be disposed on the active region ACT.

The word line WL may include a gate electrode 115 extending in the direction WD, and a gate insulating pattern 110 may be interposed between the gate electrode 115 and the substrate 100. A top surface of the gate electrode 115 may be covered by a gate capping line 117, and side surfaces of the gate electrode 115 may be covered by electrically insulating gate spacers 118, i.e. silicon oxide or/and silicon nitride. Thus, the top and sides of the gate electrode 115 may be surrounded by the gate spacers 118 and the gate capping line 117. A gate line 119 may include the gate insulating pattern 110, the gate electrode 115 and the gate capping line 117.

A bottom contact pad 123 may be disposed on the active region ACT between word lines that cross different active regions. A contact 160 may have a bottom surface 160bs in contact with a bottom contact pad 123 top surface 123ts. The contact 160 may penetrate a first interlayer dielectric 124 and a second interlayer dielectric 130. The contact 160 may be connected to a top contact pad 165. Portions of the substrate 100 where the bottom contact pad 123 is not formed may be covered with a bottom insulating pattern 121.

Bit lines 125 may extend parallel to a second direction BD that crosses the first direction WD. The bit lines 125 may be on the first interlayer dielectric 124 and in the second interlayer dielectric 130. A bit line capping pattern 126 may be disposed on a top surface of the bit line 125.

Sidewalls of the bit line 125 may be covered with second spacers 130a. The second spacers 130a may be disposed between the bit line 125 and the contact 160. Sidewalls of the bit line capping pattern 126 may be covered by first spacers 133a. A top surface of the bit line capping pattern 126 may be covered with a top spacer 133c. The first spacers 133a on sidewalls of the bit line capping patterns 126 may be disposed between the bit line capping patterns 126 and the top contact pads 165.

Protection patterns 145 may be disposed between the bit line capping patterns 126. A length of the protection pattern 145 along the second direction BD may be determined in accordance with a size of the top contact pad 165. For instance, the length of the protection pattern 145 along the second direction BD may extend to a boundary of the top contact pad 165.

The top contact pad 165 may be disposed between adjacent protection patterns 145 in the second direction BD, such that a first top contact pad 165 may be spaced apart from a second top contact pad 165 by a protection pattern 145 interposed therebetween. In an implementation, both side surfaces of the protection pattern 145 may be in contact with respective side surface of adjacent top contact pads 165, and a size of the top contact pad 165 may be determined according to the size of the protection pattern 145. The protection patterns 145 may include nitride, e.g., silicon nitride.

A bottom spacer 133b may be disposed on a top surface 130ts of the second interlayer dielectric 130. The bottom spacer 133b may expose the contact 160. The bottom surface 165bs of the top contact pad 165 may be wider than an opposing top surface 160ts of the contact 160. Accordingly, the bottom spacer 133b may be disposed between a bottom surface 165bs of the top contact pad 165 and the top surface 130ts of the second interlayer dielectric 130.

Storage nodes 170 may be disposed on the top contact pads 165. The storage nodes 170 may be in electrical contact with the top contact pads 165. In an implementation, the top contact pads 165 may be formed to have top surface 165ts having an area greater than an opposing bottom surface 170bs of the storage nodes 170. Accordingly, the area of the top surface 165ts of the top contact pad between the protection patterns 145 may be sufficient to provide an alignment margin with respect to the position of the storage node 170. Thus, electrical connections may be reliably formed between the storage nodes 170 and underlying top contact pads 165. Therefore, a contact resistance between the storage node 170 and the top contact pad 165 may be reduced, signal delays may be reduced, and operational characteristics of the device may be enhanced, e.g., a last data into row precharge time (tRDL) may be reduced.

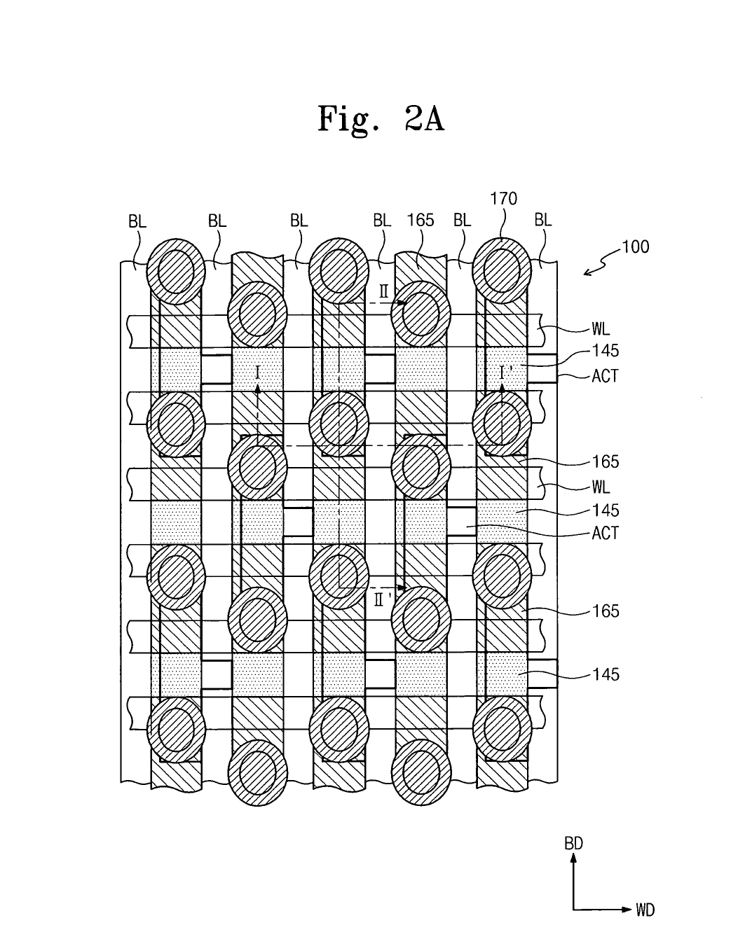

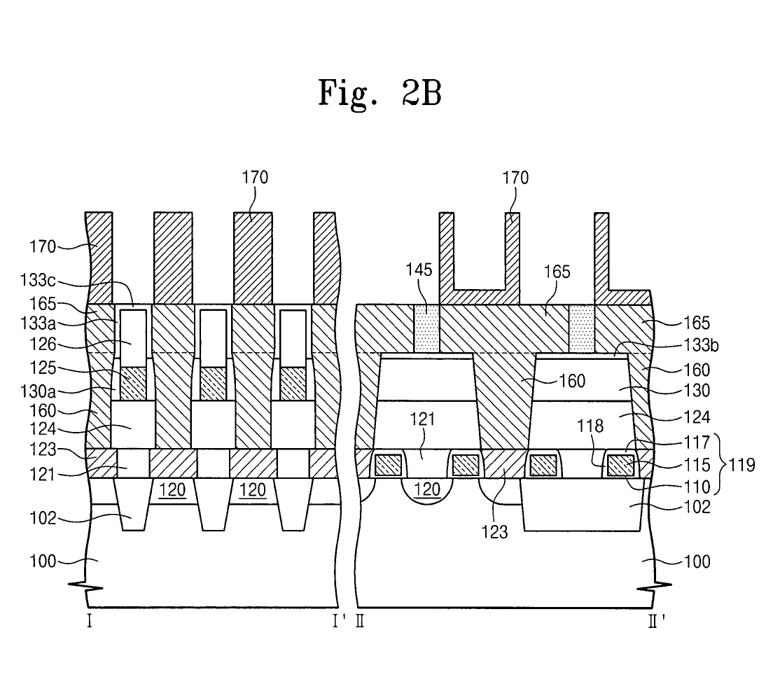

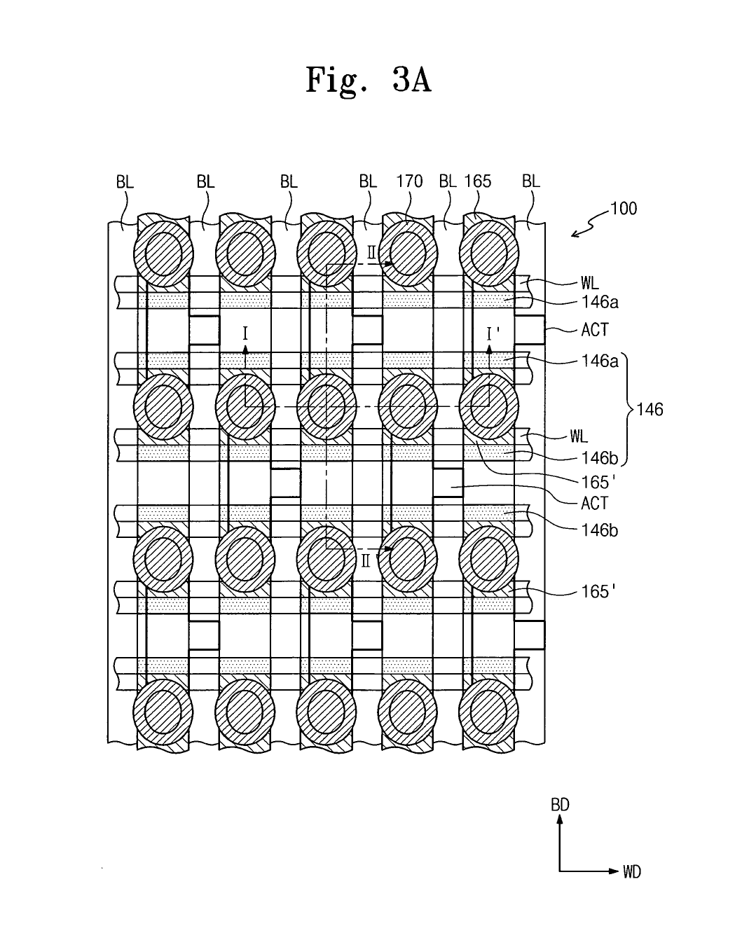

Referring to FIGS. 2A and 2B, a semiconductor device according to a second embodiment will be described, wherein a storage node 170 is disposed in a different position from that of the embodiment described above in connection with FIGS. 1A and 1B. In connection with FIGS. 2A and 2B, the detailed description of structures substantially similar to those described above in connection with FIGS. 1A and 1B will not be repeated.

Referring to FIGS. 2A, the storage nodes 170 may be arranged in an offset, i.e., zigzag, pattern on the top contact pads 165. Such a layout may allow a design rule of the semiconductor device to be reduced while maintaining a separation between adjacent storage nodes. Accordingly, spacing may be provided to reduce the likelihood of bridges occurring between storage nodes.

Referring to FIGS. 2A and 2B, the storage nodes 170 may be shifted in the second direction BD relative to the underlying top contact pads 165. The shift in alignment may be implemented in two patterns parallel to the bit lines BL, such that a first pattern parallel to the bit lines BL has the storage nodes 170 offset by a predetermined shift in the second direction BD, and a second pattern parallel to the bit lines BL and between adjacent first patterns has the storage nodes 170 offset by an opposite shift in the second direction BD. The alternating offsets may thus produce the zigzag pattern of storage nodes 170 shown in FIG. 2A. It will be appreciated that the margin resulting from the difference in size between the bottom surface 170bs of the storage node 170 with respect to the top surface 165ts of the top contact pad 165 in the second direction BD enables the storage nodes 170 to be shifted relative to the top contact pads 165 while maintaining electrical contact therebetween. In an implementation, as shown in FIG. 2B, the edges of the bottom surfaces 170bs of the storage nodes 170 may be substantially aligned with edges of the top surfaces 165ts of the top contact pads 165 (see cross-section II-II′ in FIG. 2B).

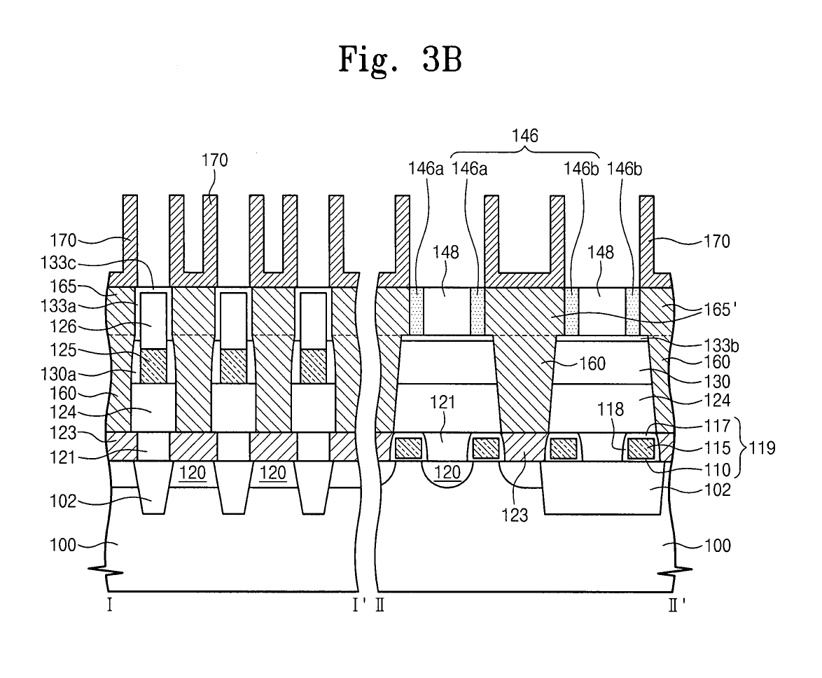

Referring to FIGS. 3A and 3B, a semiconductor device according to a third embodiment will be described, wherein a top contact pad 165′ and a protection pattern 146 that are different from the previously described top contact pad 165 and protection pattern 145 are provided.

Referring to FIGS. 3A and 3B, a top contact pad 165′ may be in contact with a first sub protection pattern 146a paired with a second sub protection pattern 146b (first and second protection patterns 146a and 146b are collectively referred to as protection pattern 146). The first and second sub protection patterns 146a and 146b may be in contact with both sides of the top contact pad 165′, and may be between adjacent contact pads 165′ in the second direction BD.

An oxide pattern 148 may be disposed between adjacent first sub protection patterns 146a, such that a first sub protection pattern 146a is disposed between the oxide pattern 148 and the top contact pad 165′ in the second direction BD. Similarly, another oxide pattern 148 may be disposed between adjacent second sub protection pads 146b.

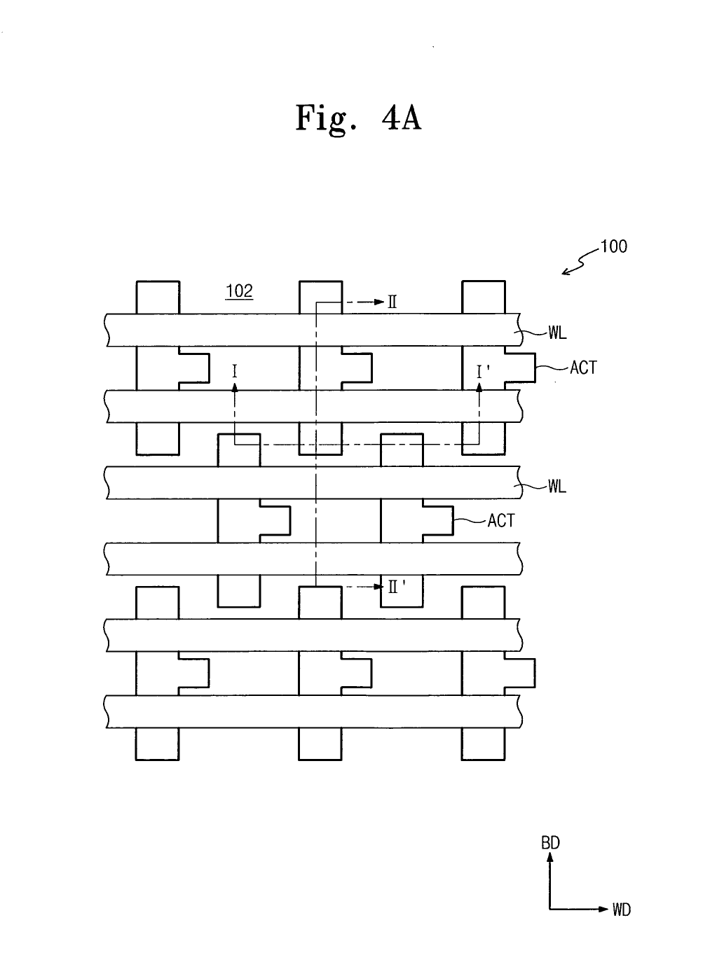

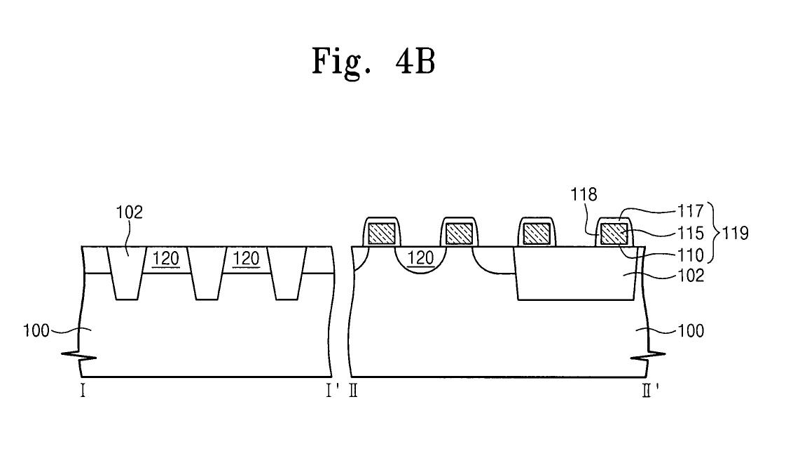

A method of forming a semiconductor device according to an embodiment will now be described in connection with FIGS. 4A to 11B.

Referring to FIGS. 4A and 4B, device isolation layers 102 may be formed in a semiconductor substrate 100 to define active regions ACT. The device isolation layers 102 may be formed by, e.g., a shallow trench isolation (STI) process.

A gate insulation layer (not shown) for the gate insulating pattern 110 may be formed on the semiconductor substrate 100. The gate insulating layer may be an oxide layer formed using, e.g., a thermal oxidation process. A gate conductive layer (not shown) for the gate electrode 115 may be formed on the gate insulating layer. The gate conductive layer may be, e.g., a single layer including doped polysilicon, or a multi-layer structure including a doped polysilicon layer, a silicide layer and/or a metal layer. A gate capping layer (not shown) for the gate capping line 117 may be formed on the gate conductive layer. The gate capping layer may be, e.g., a silicon nitride layer, and may protect the gate conductive layer during a subsequent etching operation.

The gate line 119 including the gate insulating pattern 110, the gate electrode 115 and the gate capping line 117 may be formed by patterning the gate capping layer, the gate conductive layer and the gate insulating layer. The gate electrode 115 may extend along the first direction WD to form the word line WL.

Impurities may be implanted into the active regions ACT using the gate lines 119 as a mask, thereby forming impurity regions 120. Gate spacers 118 may be formed on sidewalls of the gate electrodes 115.

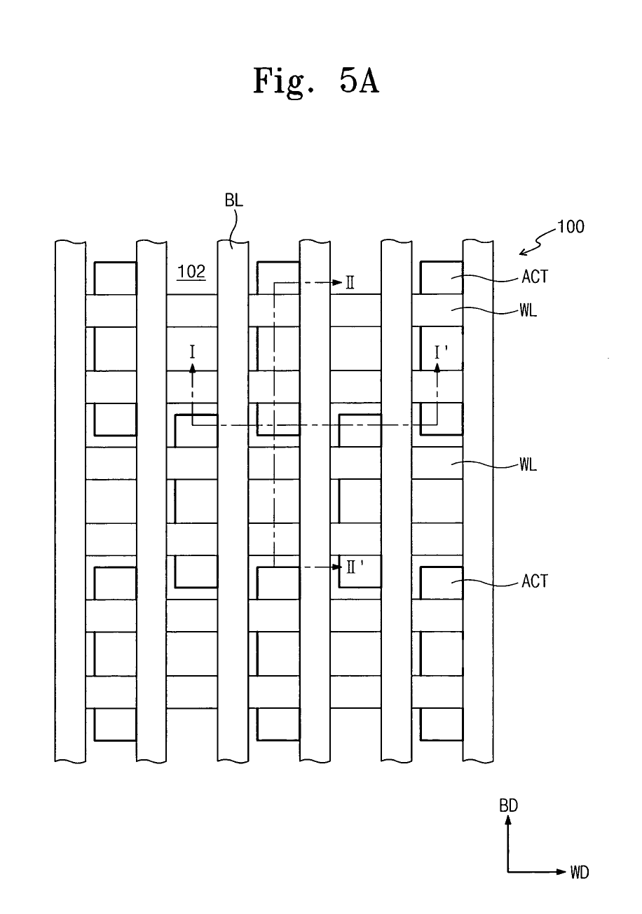

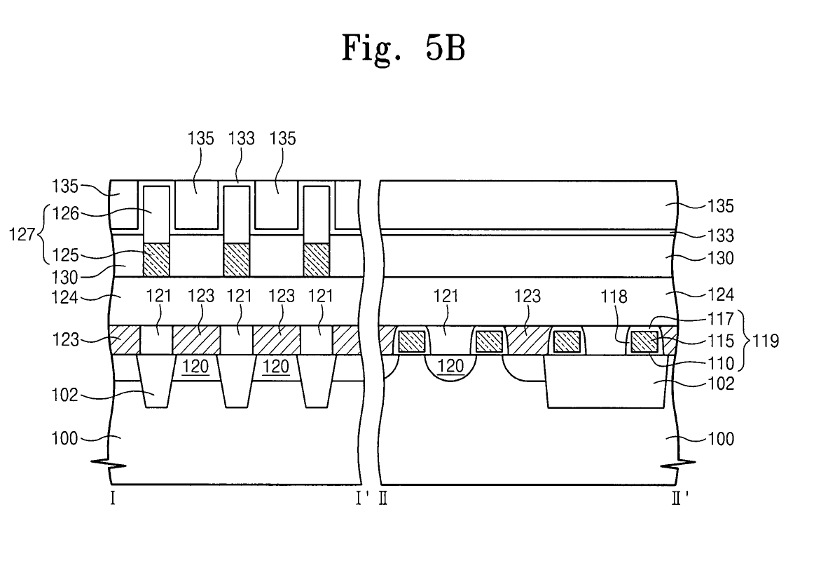

Referring to FIGS. 5A and 5B, a first insulating layer (not shown) for the bottom insulating pattern 121 may be formed on the gate lines 119 and the substrate 100. The first insulating layer may be planarized down to the top surface of the gate lines 119 to form the bottom insulating patterns 121 between the gate lines 119.

Portions of the bottom insulating patterns 121 may be removed so that the substrate 100 between the gate lines 119 is exposed. In the exposed regions, bottom contact pad regions may be formed on the impurity regions 120, and the bottom contact pad regions may be filled with conductive material to form the bottom contact pads 123.

The first interlayer dielectric 124 may be formed on the gate lines 119, the bottom insulating patterns 121 and the bottom contact pads 123. The first interlayer dielectric 124 may be, e.g., a silicon oxide layer.

A bit line conductive layer (not shown) for the bit lines 125 and a bit line capping layer (not shown) for the bit line capping patterns 126 may be formed on the first interlayer dielectric 124. The bit line conductive layer may include, e.g., a metal material such as tungsten. The bit line capping layer may include, e.g., silicon nitride. The bit line capping layer and the bit line conductive layer may be patterned to form the bit line stacks 127 each including a bit line 125 and a bit line capping pattern 126. The bit lines 125 may extend along the second direction BD crossing the first direction WD. In an implementation, a bit line spacer (not shown) may be formed on a sidewall of the bit line stack 127. The bit line spacer may help prevent oxidation of the bit line 125.

A second insulating layer (not shown) for the second interlayer dielectric 130 may be formed on the bit line stack 127 and the first interlayer dielectric 124. The second insulating layer may be recessed to form the second interlayer dielectric 130 using, e.g., a wet etching process. A top surface and an upper portion of a sidewall of the bit line stack 127 may be exposed by the recessing that forms the second interlayer dielectric 130. In an implementation, the second insulating layer may be recessed only to expose the bit line capping pattern 126 of the bit line stack 127.

A spacer layer 133 may be formed on the top surface and the upper portion of the sidewall of the bit line stack 127, and on the second interlayer dielectric 130. The spacer layer 133 may be, e.g., a conformal layer such as a silicon nitride layer.

A third insulating layer (not shown) for the third interlayer dielectric 135 may be formed on the spacer layer 133. The third insulating layer may be planarized to form the third interlayer dielectric 135. The planarization may be performed by a chemical mechanical polishing (CMP) process using the spacer layer 133 on the bit line stack 127 as a polishing stop.

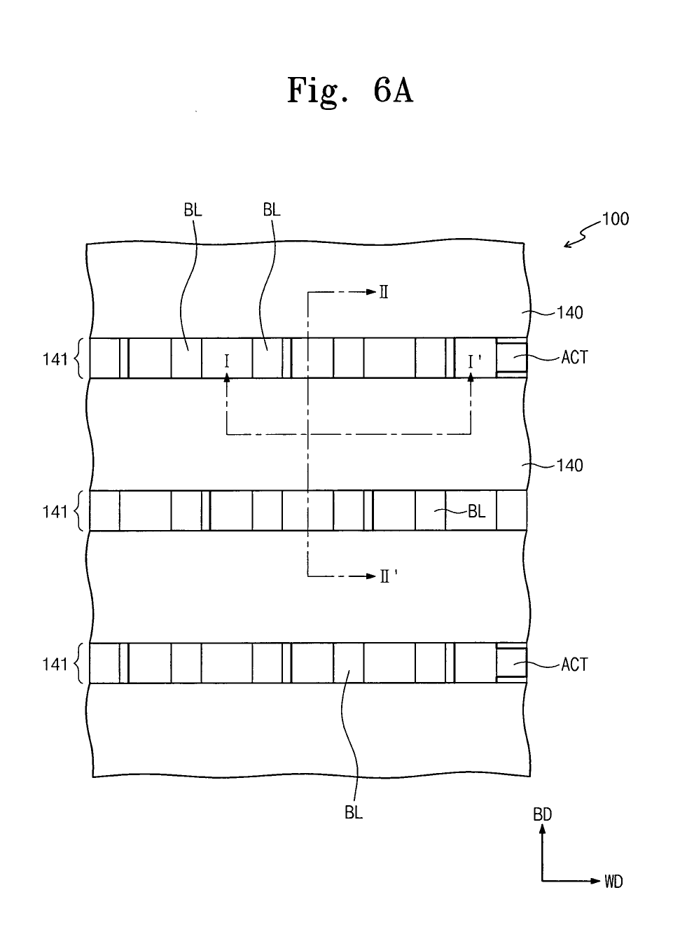

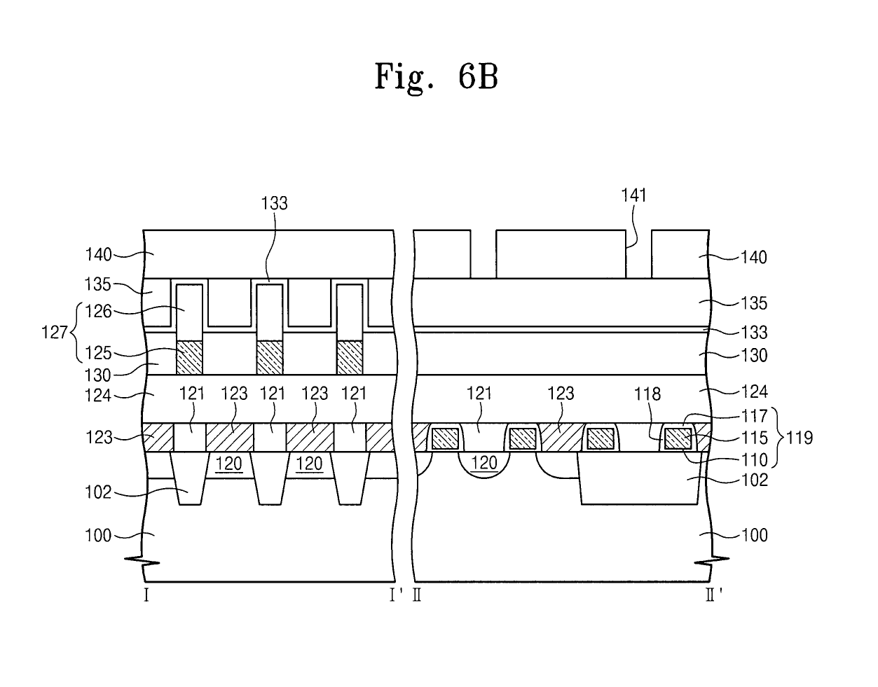

Referring to FIGS. 6A and 6B, a mask pattern 140 having linear mask openings 141 may be formed on the third interlayer dielectric 135. The mask openings 141 may have major axes parallel to the first direction WD. Portions of the third interlayer dielectric 135 and the spacer layer 133 on the bit line stack 127 may be exposed through the mask openings 141. A bottom insulating pattern 121 between the word lines WL may be directly under a mask opening 141.

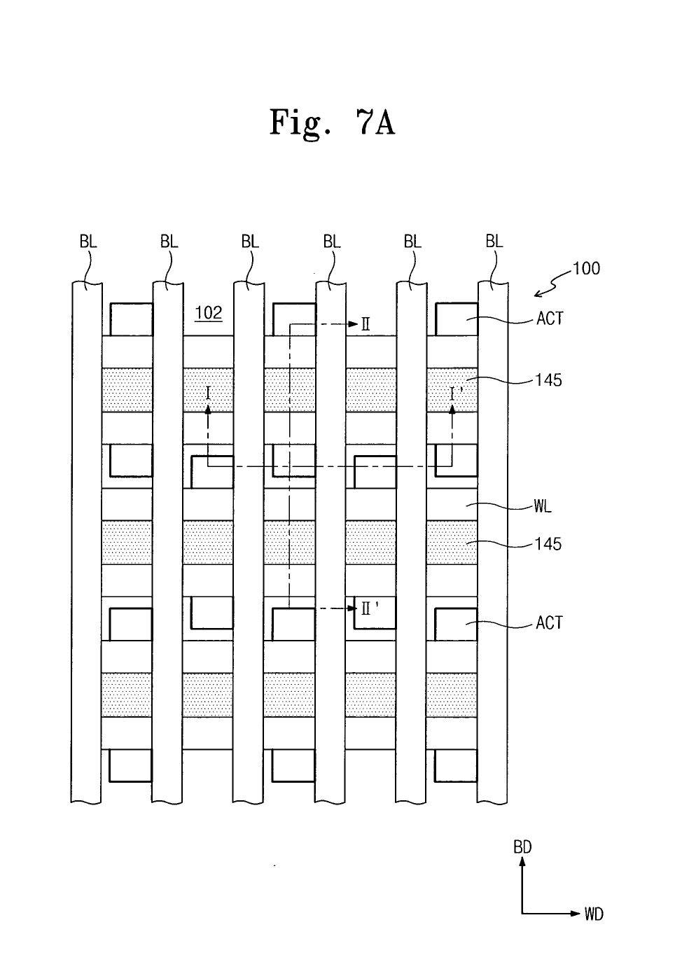

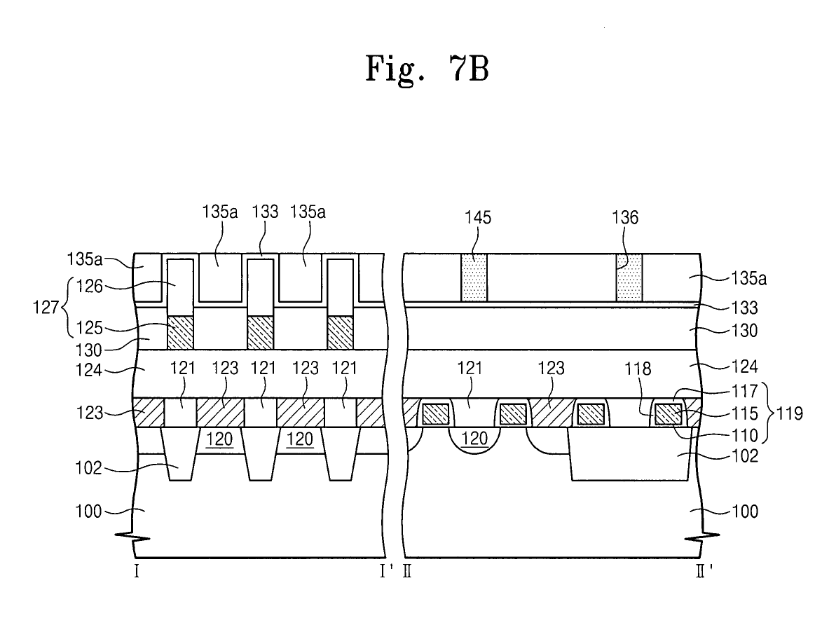

Referring to FIGS. 7A and 7B, the third interlayer dielectric 135 may be etched using the mask pattern 140 to expose the spacer layer 133, thereby forming line openings 136 and a top insulating pattern 135a. During etching, the third interlayer dielectric 135 may be removed faster than the mask pattern 140 and the spacer layer 133. In an implementation, the third interlayer dielectric 135 may include silicon oxide, and the mask pattern 140 and the spacer layer 133 may include silicon nitride. The mask pattern 140 may be removed after etching the third dielectric layer 135.

A protection insulating layer (not shown) for the protection patterns 145 may be formed on the top insulating pattern 135a so as to fill the line openings 136. The protection insulating layer may be planarized to form the protection patterns 145 in the line openings 136. The planarization may be performed, e.g., by a CMP operation, to expose the spacer layer 133 on the bit line stack 127 and the top insulating pattern 135a. Even if the spacer layer 133 is damaged, the bit line 125 may be protected by the bit line capping pattern 126.

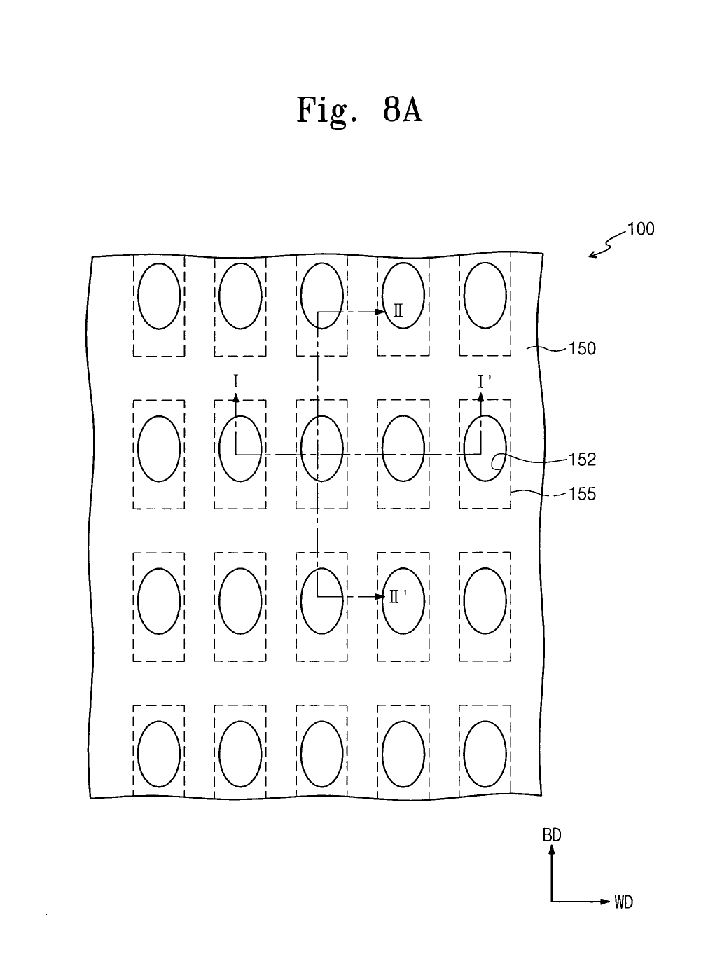

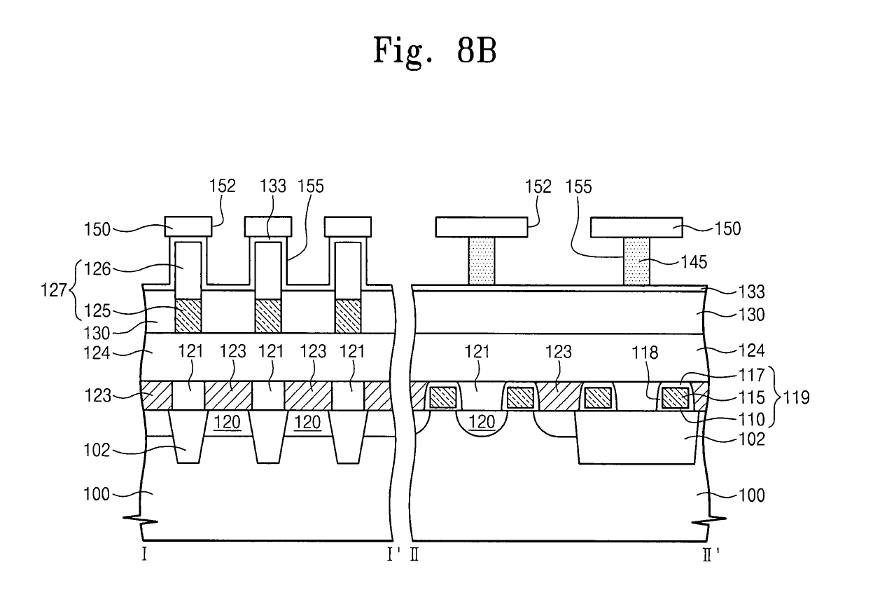

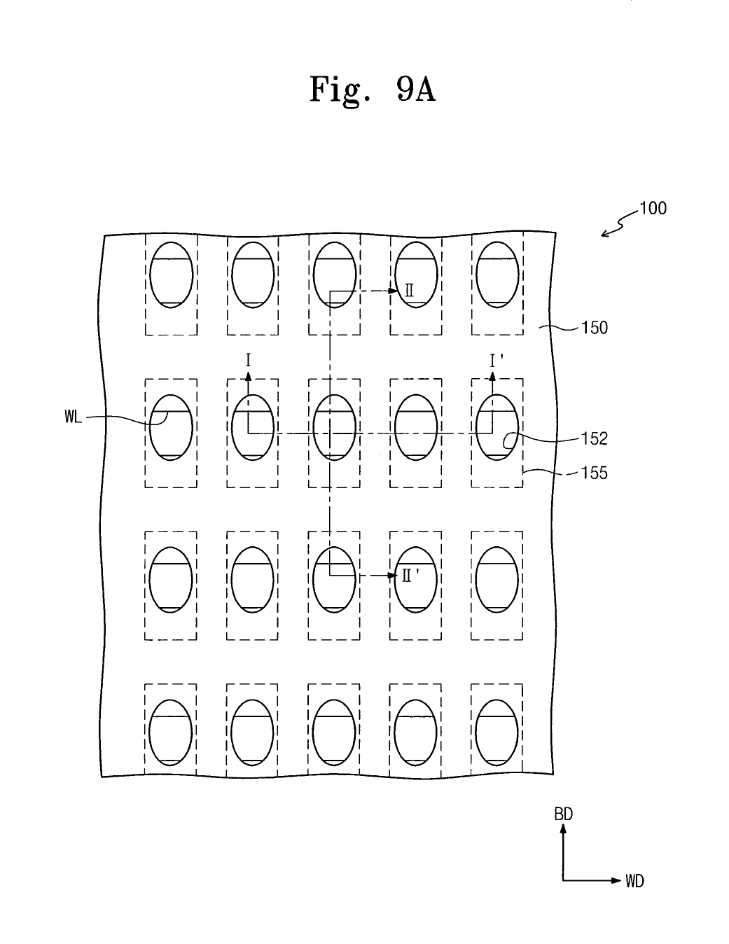

Referring to FIGS. 8A and 8B, an etching mask 150 may be formed on the top insulating pattern 135a, the protection patterns 145 and the spacer layer 133 on the bit line stacks 127. The etching mask 150 may include, e.g., undoped polysilicon. The etching mask 150 may include etching openings 152 exposing portions of the top insulating pattern 135a.

The top insulating pattern 135a may be removed using the etching mask 150 to form a contact pad region 155. An isotropic etching operation may be performed to remove the top insulating pattern 135a. An etching solution may be provided through the etching opening 152, and the top insulating pattern 135a may be removed faster than the etching mask 150, the spacer layer 133 and the protection pattern 145. The isotropic etching may be performed for a time sufficient to completely remove the top insulating pattern 135a.

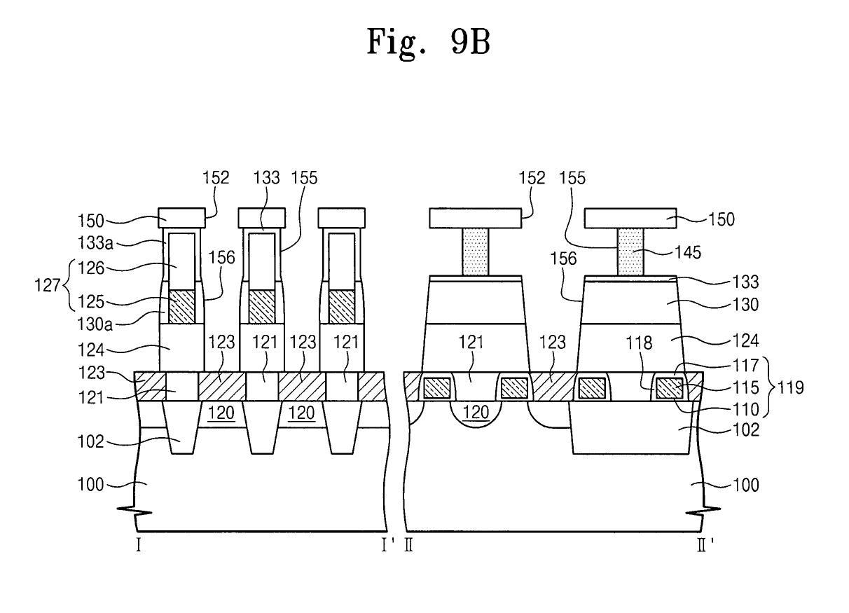

Referring to FIGS. 9A and 9B, an anisotropic etching operation may be performed using the etching mask 150. The spacer layer 133, the second interlayer dielectric 130 and the first interlayer dielectric 124 that are exposed by the etching opening 152 may be sequentially etched to form contact regions 156 connected to the contact pad regions 155. The contact regions 156 may expose the bottom contact pads 123. The anisotropic etching operation used to form the contact regions 156 by etching through the etching openings 152 may result in a cross sectional area of the contact regions 156, as determined parallel to the substrate 100, being formed to be smaller than that of the contact pad regions 155. When the contact region 156 is formed, first and second spacers 133a and 130a may be formed from the spacer layer on sidewalls of the bit line stack 127.

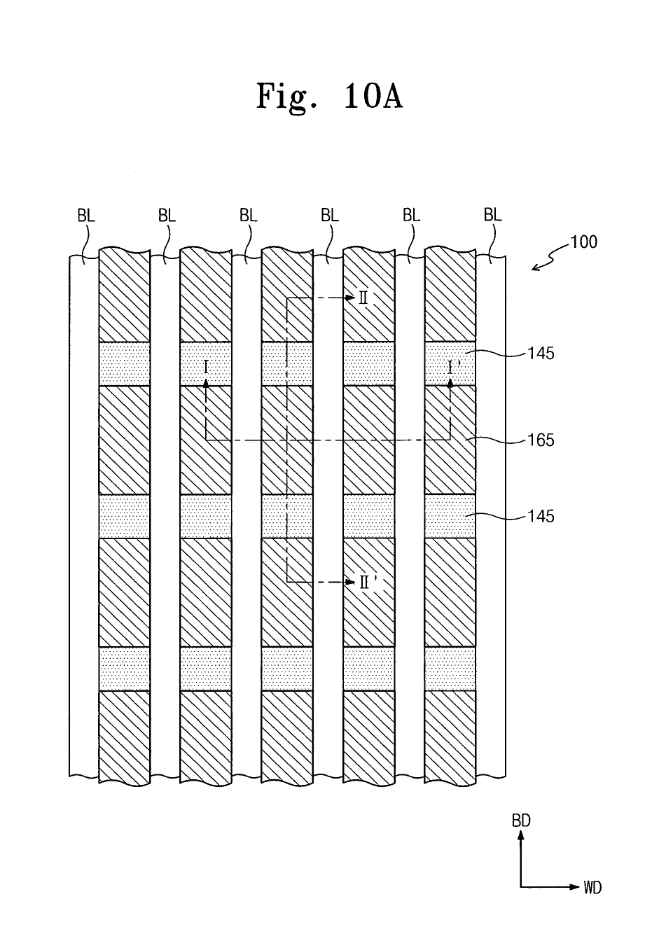

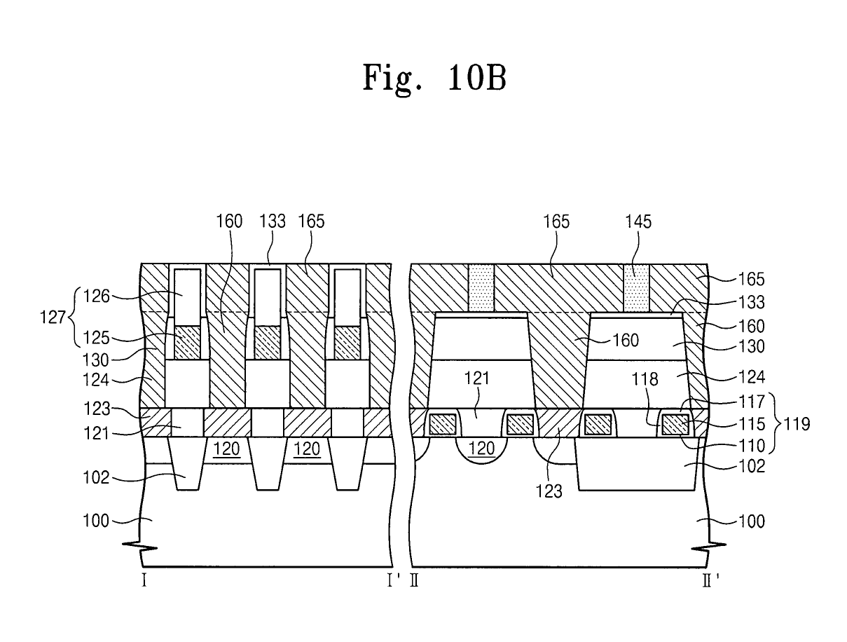

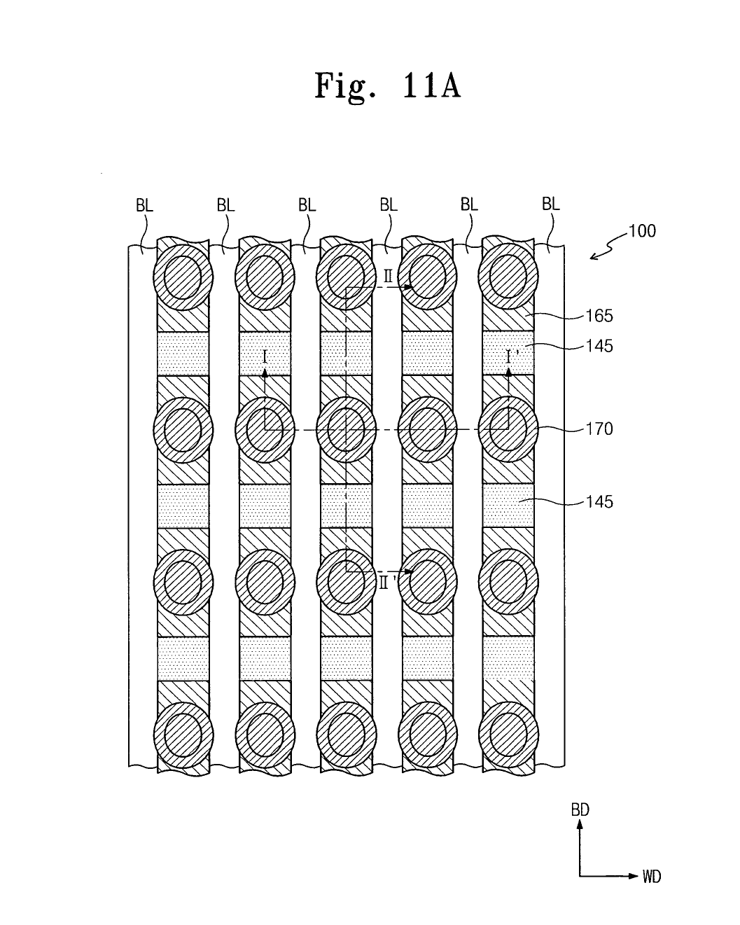

Referring to FIGS. 10A and 10B, the etching mask 150 may be removed. The contact pad regions 155 and the contact regions 156 may be filled to form the top contact pad 165 and the contact 160, respectively. Formation of a conductive layer (not shown) and planarization of the conductive layer may be performed to form the contact 160 and the top contact pad 165. A plurality of the top contact pads 165 may be formed with the protection patterns 145 interposed between the top contact pads 165.

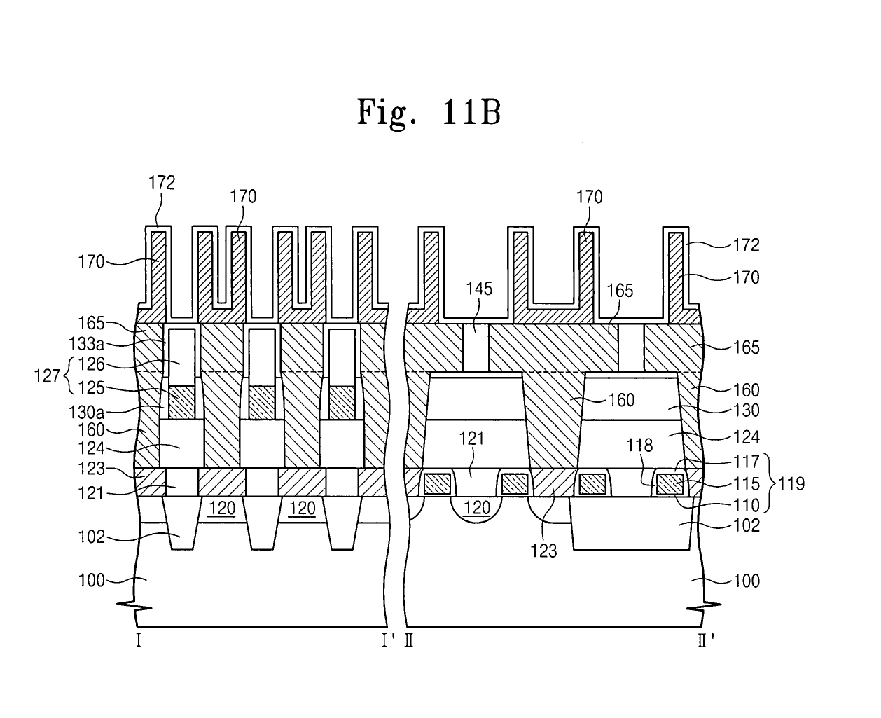

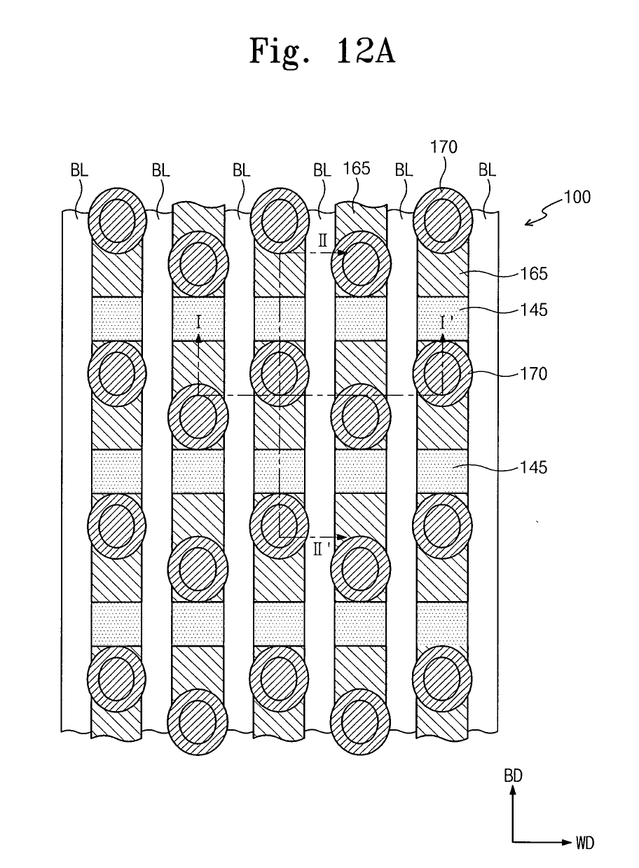

Referring to FIGS. 11A and 11B, storage nodes 170 may be formed on corresponding top contact pads 165. In an embodiment, the storage nodes 170 may be formed to be substantially centered on the top contact pads 165. A dielectric layer 172 and top electrodes (not shown) may be formed on the storage nodes 170 to form capacitors.

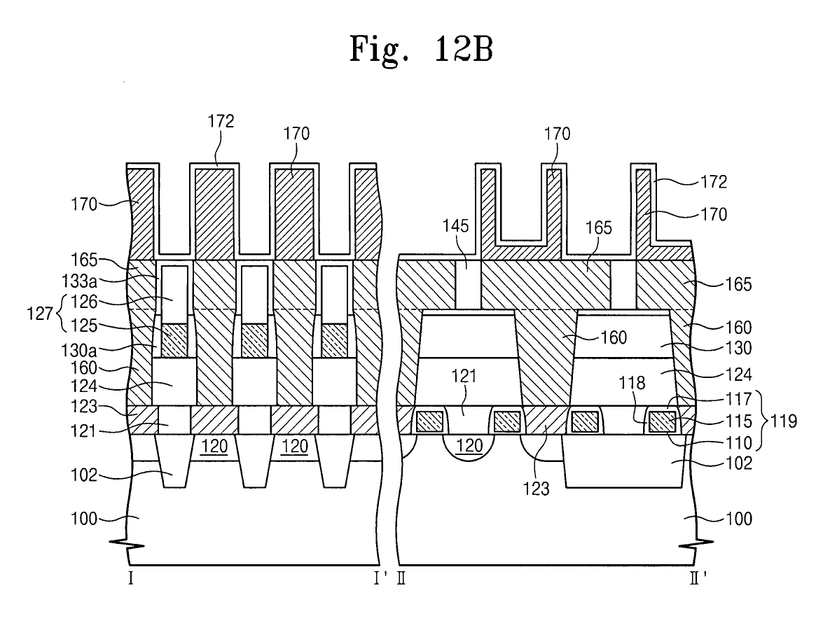

Referring to FIGS. 12A and 12B, a method of forming a semiconductor device according to another embodiment will be described. The operations described above in connection with FIGS. 4A to 10B may precede the operations described below in connection with FIGS. 12A and 12B, and details of the previously described operations will not be repeated.

Referring to FIGS. 12A and 12B, the storage nodes 170 may be formed in zigzag patterns on the top contact pads 165. Accordingly, if a design rule is reduced, the formation of bridges between adjacent storage nodes 170 may be reduced or prevented. Larger spacing between the storage nodes 170 is expected to reduce bridge formation. In this embodiment, a space between the storage nodes 170 arranged in zigzags may be greater than in the case where the storage nodes 170 are arranged in lines along the first direction WD.

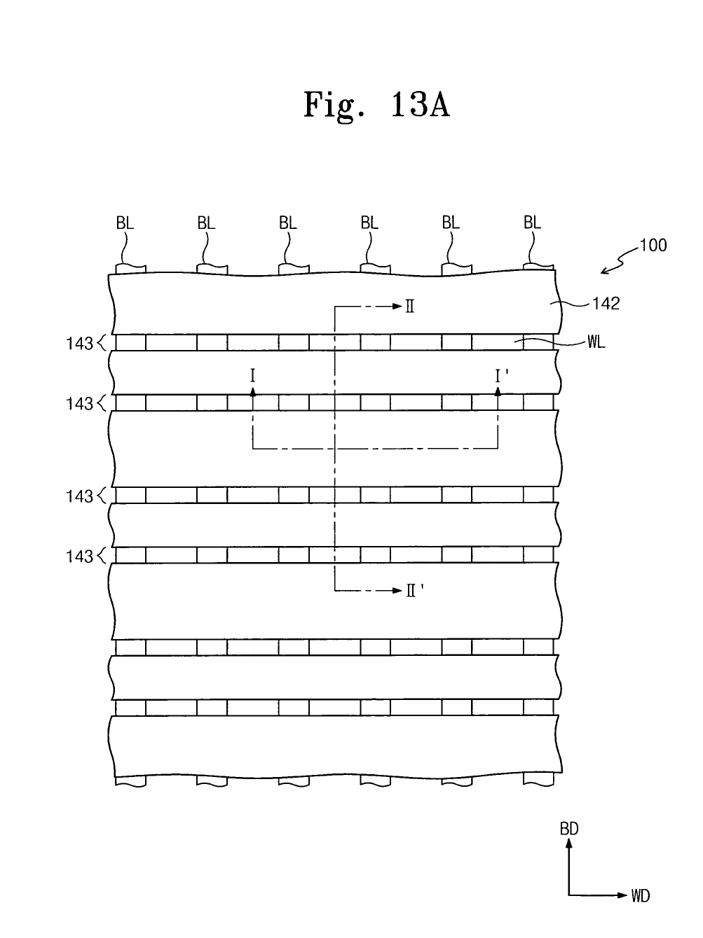

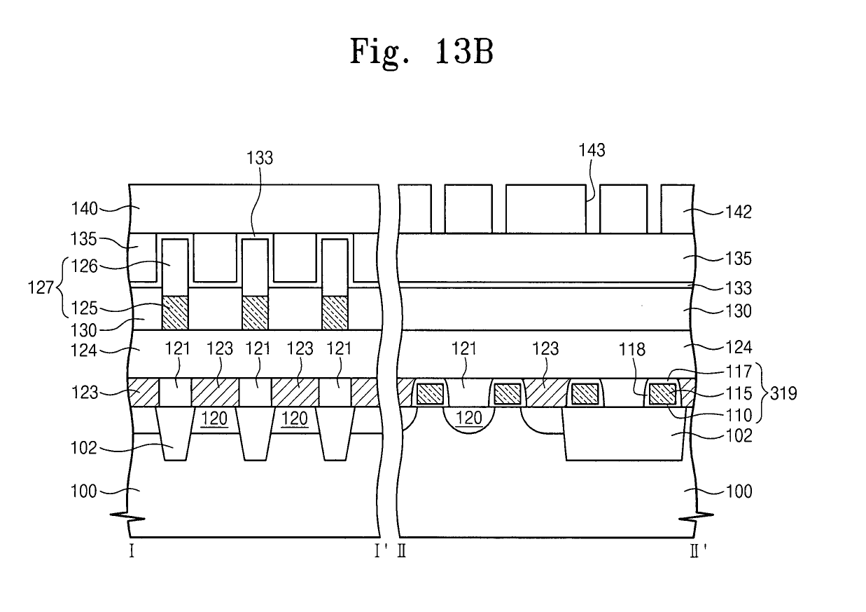

Referring to FIGS. 13A to 16B, a method of forming a semiconductor device according to another embodiment will be described.

In similar fashion to the above-described operations, the device isolation layers 102 may be formed in a semiconductor substrate 100 to define active regions ACT. The gate lines 119 each including the gate insulating pattern 110, the gate electrode 115 and the gate capping line 117 may be formed on the substrate 100. The gate electrodes 115 may form word lines extending parallel to the first direction WD. Impurities may be implanted into the active regions ACT using the gate lines 119 as a mask to form impurity regions 120. The gate spacers 118 may be formed on the sidewalls of the gate lines 119. The bottom contact pads 123 may be formed on the active regions ACT between the word lines WL crossing different active regions ACT. The bottom insulating patterns 121 may be formed on the substrate 100 where the bottom contact pads 123 are not formed. The first interlayer dielectric 124 may be formed on the gate lines 119, the bottom insulating patterns 121 and the bottom contact pads 123. The first interlayer dielectric 124 may be, e.g., silicon oxide. The bit line stacks 127 each including a bit line 125 and a bit line capping pattern 126 may be formed on the first interlayer dielectric 124. The bit lines 125 may include a metal material such as tungsten and the bit line capping pattern 126 may include silicon nitride. The second interlayer dielectric 130 may be formed to expose the top surfaces and the upper portions of the sidewalls of the bit line stacks 127. The spacer layer 133 may be formed on the second interlayer dielectric 130, and the top surfaces and the exposed upper portions of the sidewalls of the bit line stacks 127. The spacer layer 133 may be, e.g., silicon nitride. An insulating layer (not shown) may be formed on the spacer layer 133 and planarized to form the third interlayer dielectric 135.

Referring to FIGS. 13A and 13B, a mask pattern 142 having linear mask openings 143 may be formed on the third interlayer dielectric 135. The mask openings 143 may have major axes oriented parallel to the first direction WD. Portions of the third interlayer dielectric 135 and the spacer layer 133 on the bit line stacks 127 may be exposed through the mask openings 143. The word lines WL may extend on the substrate 100 under the mask openings 143.

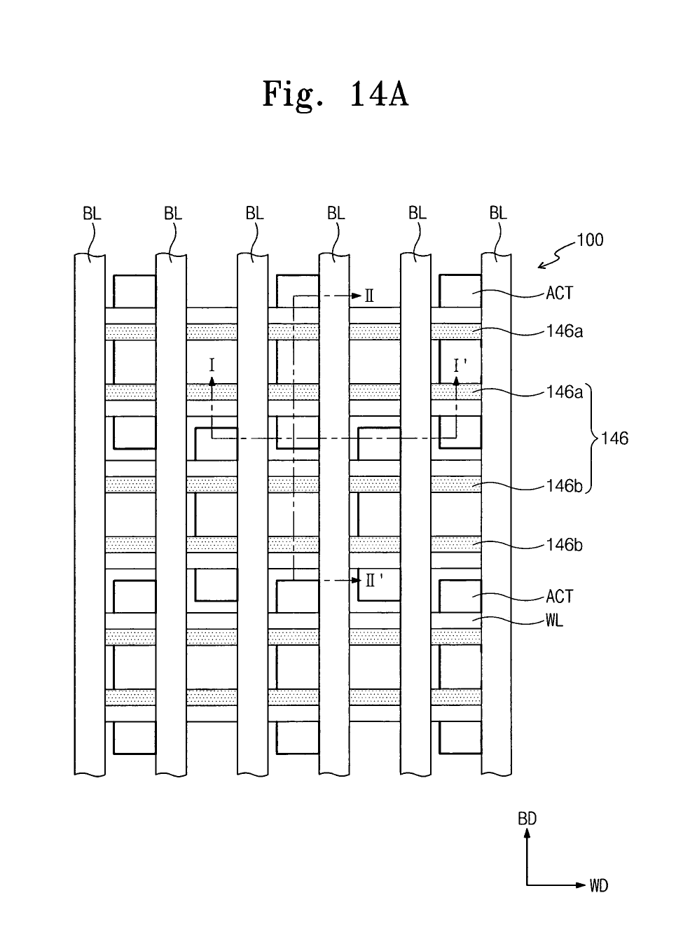

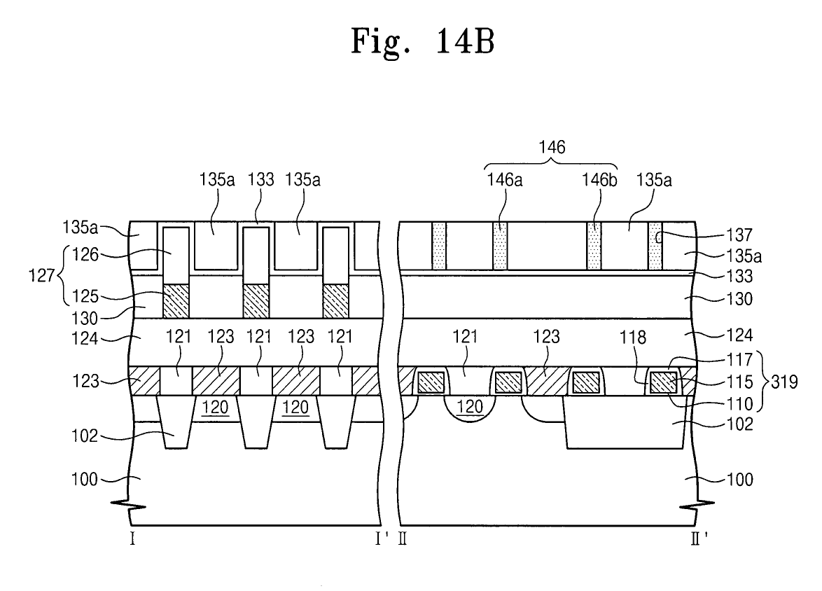

Referring to FIGS. 14A and 14B, the third interlayer dielectric 135 may be etched using the mask pattern 142 to expose the spacer layer 133, thereby forming line openings 137 and a top insulating pattern 135a. The line openings 137 may be filled, e.g., with silicon nitride, to form the protection patterns 146 including the first protection patterns 146a and the second protection patterns 146b. The first protection patterns 146a may be formed on the active regions ACT, and the second protection patterns 146b may be formed on the device isolation layers 102.

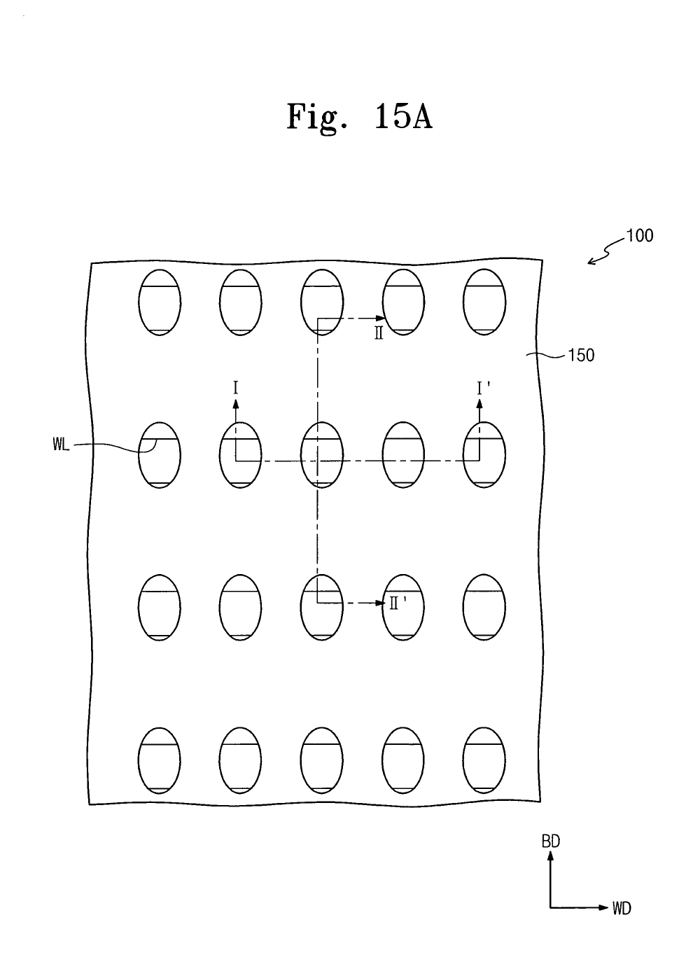

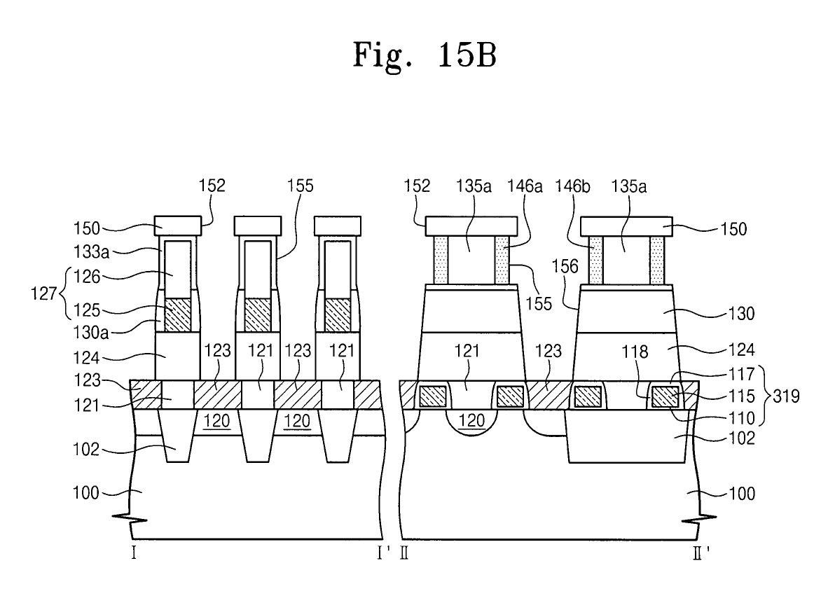

Referring to FIGS. 15A and 15B, an etching mask 150 may be formed on the spacer layer 133 disposed on the top insulating pattern 135a, the protection patterns 146 and the bit line stacks 127. The etching mask 150 may have etching openings 152 exposing portions of the top insulating patterns 135a. The etching openings 152 may expose portions of the top insulating patterns 135a spaced apart by the protection patterns 146. The bottom contact pads 123 may be disposed directly under the etching openings 152.

The top insulating patterns 135a may be removed using the etching mask 150 to form the contact pad regions 155. An anisotropic etching operation may be performed using the etching mask 150 to form the contact regions 156 connected to the contact pad regions 155. The first and second spacers 133a and 130a may be formed on the sidewalls of the bit line stacks 127.

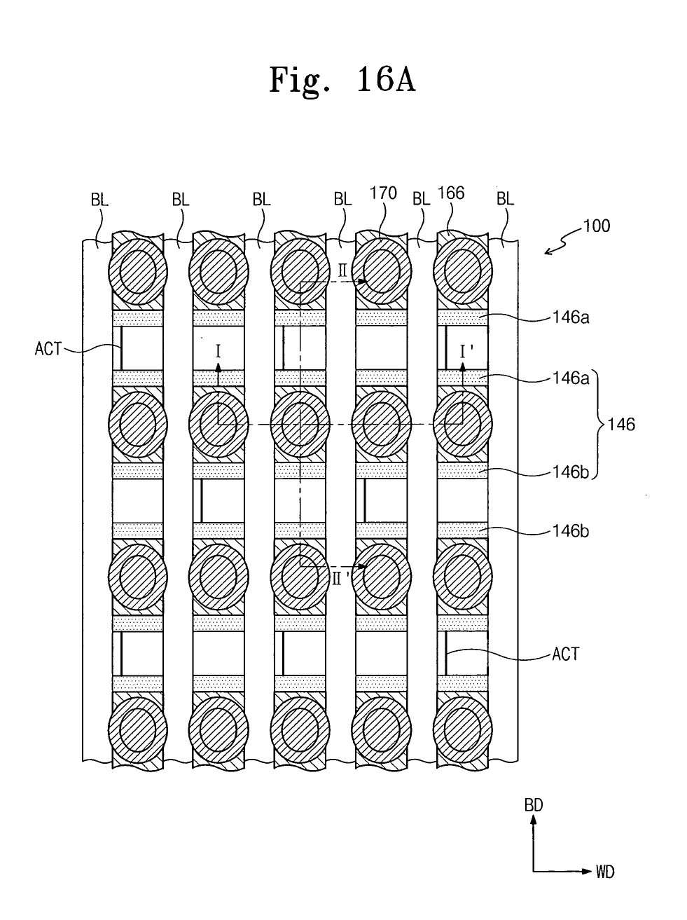

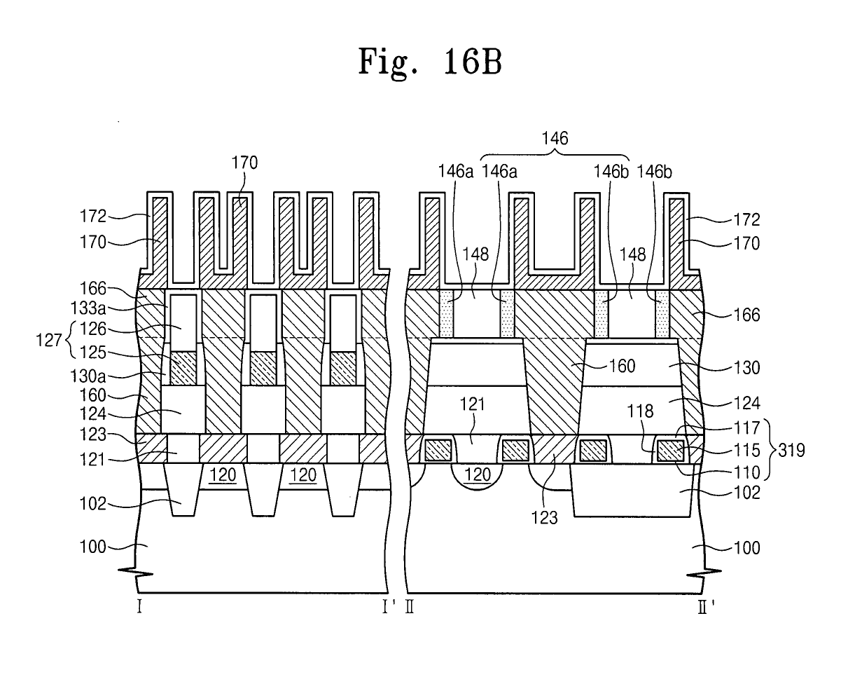

Referring to FIGS. 16A and 16B, the etching mask 150 may be removed. The contact regions 156 and the contact pad regions 155 may be filled to form the contacts 160 and the top contact pad regions 166. The storage nodes 170 may be formed on the top contact pad regions 166. The dielectric layer 172 and top electrodes (not shown) may be formed on the storage nodes 170 to form capacitors.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope as set forth in the following claims.

What is claimed is:

1. A semiconductor device, comprising:
conductive lines on a substrate;
sidewall spacers on sidewalls of the conductive lines;
contacts between the conductive lines, the contacts separated from the conductive lines by the sidewall spacers and electrically connected to active regions of the substrate;
contact pads on and electrically connected to corresponding contacts;
protection patterns contacting side surfaces of the contact pads, the protection patterns being disposed between the contact pads in a first direction crossing the conductive lines; and
storage nodes on and electrically connected to corresponding contact pads.

2. The device as claimed in claim 1, wherein a bottom surface of the contact pad is wider in the first direction than an opposing top surface of the corresponding contact.

3. The device as claimed in claim 1, wherein a top surface of the contact pad is wider in the first direction than an opposing bottom surface of a corresponding storage node.

4. The device as claimed in claim 3, wherein the storage nodes are substantially centered on the contact pads.

5. The device as claimed in claim 3, wherein at least some of the storage nodes are offset in the first direction with respect to the corresponding contact pads.

6. The device as claimed in claim 1, further comprising:
an interlayer dielectric directly under portions of the contact pads; and
bottom spacers on an upper surface of the interlayer dielectric below the portions of the contact pads, wherein the bottom spacers include silicon nitride.

7. The device as claimed in claim 6, further comprising a capping line on top surfaces of the conductive lines, the capping line and the bottom spacers being a same material.

8. The device as claimed in claim 7, wherein the contact pads are in contact with the capping line.

9. The device as claimed in claim 8, wherein the sidewall spacers are in contact with the contact pads, the sidewall spacers and the bottom spacers being the same material.

10. The device as claimed in claim 6, wherein the protection patterns have a same height as the portions of the contact pads.

11. A method of forming a semiconductor device, comprising:
forming conductive lines on a substrate;
forming sidewall spacers on sidewalls of the conductive lines;
forming contacts between the conductive lines, the contacts separated from the conductive lines by the sidewall spacers and electrically connected to active regions of the substrate;
forming contact pads on and electrically connected to corresponding contacts;
forming protection patterns contacting side surfaces of the contact pads, the protection patterns being disposed between the contact pads in a first direction crossing the conductive lines; and
forming storage nodes on and electrically connected to corresponding contact pads.

12. The method as claimed in claim 11, further comprising:
forming a spacer layer over a first insulating layer between the conductive lines,
forming a second insulating layer on the spacer layer,
planarizing the second insulating layer using the spacer layer as a stop layer,
forming a first etching mask on the planarized second insulating layer, and
anisotropically etching the spacer layer and the first insulating layer through openings in the first etching mask, wherein the first insulating layer forms the sidewall spacers on the conductive lines.

13. The method as claimed in claim 12, further comprising:
forming a capping pattern on each conductive line, the capping patterns each having a width substantially equal to the underlying conductive line,
wherein the spacer layer is formed on a top surface and sidewalls of each capping pattern.

14. The method as claimed in claim 12, wherein forming the protection patterns includes:
forming a plurality of linear open regions by etching portions of the second insulating layer to expose the spacer layer,
filling the open regions with a protection material, and
planarizing the protection material using the spacer layer as a stop layer.

15. The method as claimed in claim 14, wherein forming the open regions includes:
forming a second etching mask on the spacer layer and on the second insulating layer, the second etching mask having openings that cross the conductive lines, and
etching the second insulating layer through the openings in the second etching mask using an etching operation that etches the second insulating layer faster than the spacer layer.

16. The method as claimed in claim 12, further comprising isotropically etching the second insulating layer overlying the spacer layer using the first etching mask to define contact pad regions in the second insulating layer.

17. The method as claimed in claim 16, wherein the first etching mask includes polysilicon, the spacer layer and the protection patterns include silicon nitride, and the second insulating layer includes silicon oxide.

18. The method as claimed in claim 11, wherein:
forming the protection patterns includes forming one first protection pattern and two second protection patterns between adjacent contact pads,
each first protection pattern is formed between a pair of second protection patterns, and
the second protection patterns protect the first protection patterns during an etching operation used to define contact pad regions between adjacent second protection patterns.

19. The method as claimed in claim 18, wherein the etching operation is isotropic, and
a first etching mask is formed to cover the one first protection pattern and two second protection patterns between the adjacent contact pads prior to the etching operation.

20. A method of forming a semiconductor device, comprising:
forming a first insulating layer exposing a top surface and an upper portion of a side surface of line patterns on a substrate;
forming a spacer layer on the first insulating layer and the exposed surface of the line patterns;
forming an insulating pattern on the spacer layer to fill a space between the line patterns;
forming protection patterns in contact with the spacer layer along a direction of crossing the line patterns in the insulating pattern;
defining a contact pad region between the protection patterns;
defining a contact region exposing the substrate by etching the spacer layer and the first insulating layer through the contact pad region;
filling the contact region and the contact pad region with conductive material to form a contact and a contact pad; and
forming a storage node on the contact.
